(19) United States
(12) Patent Application Publication
(10) Pub. No.: US 2026/0018211 A1
(43) Pub. Date: Jan. 15, 2026

(54) SEMICONDUCTOR DEVICE AND METHOD OF OPERATING THEREOF, SYSTEM, AND COMPUTER READABLE STORAGE MEDIUM

(71) Applicant: Yangtze Memory Technologies Holding Co., Ltd., Wuhan (CN)

(72) Inventors: Lei Guan, Wuhan (CN); Wendong Wang, Wuhan (CN); Feng Xu, Wuhan (CN); Tingze Wang, Wuhan (CN); Anyi Zhu, Wuhan (CN); Lei Jin, Wuhan (CN); Zongliang Huo, Wuhan (CN)

(21) Appl. No.: 19/238,088

(22) Filed: Jun. 13, 2025

(30) Foreign Application Priority Data
Jul. 12, 2024 (CN) 202410940293.5

(51) Int. Cl. G11C 16/04; G11C 7/16; G11C 16/10; G11C 16/34; H01L 23/00; H01L 25/065; H01L 25/18; H10B 80/00

(52) U.S. Cl. CPC G11C 16/0483; G11C 7/16; G11C 16/10; G11C 16/3459; H01L 24/08; H01L 25/0657; H01L 25/18; H10B 80/00; H01L 2224/08145; H01L 2924/1431; H01L 2924/14511

(57) ABSTRACT

According to one aspect of the present disclosure, a semiconductor device is provided. The semiconductor device may include a memory array and a peripheral circuit coupled to the memory array. The peripheral circuit may be configured to, during a program phase of a first program loop, apply a first program voltage to a first word line and apply a second program voltage to a second word line adjacent to the first word line. An absolute value of a difference between the first program voltage and the second program voltage may be less than a first preset value. The peripheral circuit may be configured to, during the program phase of the first program loop, apply a first pass voltage to a third word line. The first pass voltage may be less than the first program voltage, and the first pass voltage may be less than the second program voltage.

### CROSS-REFERENCE TO RELATED APPLICATIONS

This application claims the benefit of priority to Chinese Application No. 202410940293.5, filed on Jul. 12, 2024, which is hereby incorporated by reference in its entirety.

### FIELD OF TECHNOLOGY

The present disclosure relates to, but is not limited to, a semiconductor device and an method of operating thereof, a system, and a computer readable storage medium.

### BACKGROUND

In the classical Von Neumann's computing architecture, the memory and processor are separated, and data is transmitted between them through a data bus. When executing commands, the processor first reads data from the memory, processes it, and then writes the updated data back to the memory. Frequent data migration brings huge power consumption and time overhead; in addition, due to the limited bandwidth of the memory, the processing speed of the processor is limited by the access speed of the memory, which greatly affects the computing performance. With the rise of applications such as big data and artificial intelligence, the processing of massive amounts of data has made the bottleneck of Von Neumann's computing architecture increasingly prominent.

### SUMMARY

According to one aspect of the present disclosure, a semiconductor device is provided. The semiconductor device may include a memory array. The semiconductor device may include a peripheral circuit coupled to the memory array. The peripheral circuit may be configured to, during a program phase of a first program loop, apply a first program voltage to a first word line and apply a second program voltage to a second word line adjacent to the first word line. An absolute value of a difference between the first program voltage and the second program voltage may be less than a first preset value. The peripheral circuit may be configured to, during the program phase of the first program loop, apply a first pass voltage to a third word line. The first pass voltage may be less than the first program voltage, and the first pass voltage may be less than the second program voltage.

In some implementations, the peripheral circuit may be configured to apply a verify voltage to the first word line and apply a second pass voltage to the second word line and the third word line during a verify phase of the first program loop.

In some implementations, the first preset value may range from 5V to 7V.

In some implementations, the first program voltage may be equal to the second program voltage.

In some implementations, the first word line may be coupled to a plurality of first memory cells, and the second word line may be coupled to a plurality of second memory cells. In some implementations, for each first memory cell of a plurality of first memory cells in a same memory slice, a threshold voltage of the first memory cell may be greater than a threshold voltage of a second memory cell belonging to a same memory string as the first memory cell, or a threshold voltage of the first memory cell may be less than a threshold voltage of a second memory cell belonging to a same memory string as the first memory cell, or a threshold voltage of the first memory cell may be equal to a threshold voltage of a second memory cell belonging to a same memory string as the first memory cell.

In some implementations, the peripheral circuit may be configured to apply a third program voltage to a fourth word line adjacent to the first word line while applying the first program voltage to the first word line during the program phase of the first program loop. In some implementations, the first word line may be located between the second word line and the fourth word line, and an absolute value of a difference between the first program voltage and the third program voltage may be less than a second preset value.

In some implementations, the second preset value may range from 5V to 7V.

In some implementations, the third program voltage may be equal to the first program voltage, and the second program voltage may be equal to the first program voltage.

In some implementations, the first word line may be coupled to a plurality of first memory cells, and the fourth word line may be coupled to a plurality of third memory cells. In some implementations, for each first memory cell of a plurality of first memory cells in a same memory slice, a threshold voltage of the first memory cell may be greater than a threshold voltage of a third memory cell belonging to a same memory string as the first memory cell, or a threshold voltage of the first memory cell may be less than a threshold voltage of a third memory cell belonging to a same memory string as the first memory cell, or a threshold voltage of the first memory cell may be equal to a threshold voltage of a third memory cell belonging to a same memory string as the first memory cell.

In some implementations, the peripheral circuit may be configured to apply a verify voltage to the first word line. In some implementations, the peripheral circuit may be configured to apply a second pass voltage to the second word line and the third word line. In some implementations, the peripheral circuit may be configured to apply a third pass voltage to the fourth word line during a verify phase of the first program loop.

In some implementations, the peripheral circuit may be configured to apply a fourth program voltage to the first word line while applying a fifth program voltage to the second word line during a program phase of a second program loop after the first program loop. In some implementations, an absolute value of a difference between the fourth program voltage and the fifth program voltage may be less than a third preset value, the first program voltage may be less than the fourth program voltage, the second program voltage may be less than the fifth program voltage, and a difference between the fourth program voltage and the first program voltage may be equal to a difference between the fifth program voltage and the second program voltage.

In some implementations, the peripheral circuit may be configured to apply an input voltage to the first word line and apply a fourth pass voltage to the second word line during an operation phase with the semiconductor device. In some implementations, the input voltage may correspond to a first element in an input vector or an input matrix.

In some implementations, the peripheral circuit may include an analog-to-digital conversion circuit coupled to the memory array and configured to convert an analog signal into a digital signal. In some implementations, the peripheral circuit may include a digital-to-analog conversion circuit coupled to the memory array and configured to convert a digital signal into an analog signal.

In some implementations, each memory cell in the memory array may be configured to store at least one bit of data.

In some implementations, the semiconductor device may include a three-dimensional NAND type memory.

In some implementations, the semiconductor device may include a first semiconductor structure, a bonding layer, and a second semiconductor structure stacked along a thickness direction of the semiconductor device, the memory array may be located in the first semiconductor structure, the peripheral circuit may be located in the second semiconductor structure, and the peripheral circuit may be coupled to the memory array through a bonding structure in the bonding layer.

According to another aspect of the present disclosure, a system is provided. The system may include at least one semiconductor device. The at least one semiconductor device may include a memory array. The at least one semiconductor device may include a peripheral circuit coupled to the memory array. The peripheral device may be configured to, during a program phase of a first program loop, apply a first program voltage to a first word line and apply a second program voltage to a second word line adjacent to the first word line. An absolute value of a difference between the first program voltage and the second program voltage may be less than a first preset value. The peripheral device may be configured to, during the program phase of the first program loop, apply a first pass voltage to a third word line. The first pass voltage may be less than the first program voltage, and the first pass voltage may be less than the second program voltage. The system may include a controller coupled to the semiconductor device.

In some implementations, the controller may be configured to send an input vector or an input matrix to the semiconductor device and receive an operation result of the semiconductor device.

According to a further aspect of the present disclosure, a method of operating a semiconductor device is provided. The method may include, during a program phase of a first program loop, applying a first program voltage to a first word line and applying a second program voltage to a second word line adjacent to the first word line. An absolute value of a difference between the first program voltage and the second program voltage may be less than a first preset value. The method may include, during the program phase of the first program loop, applying a first pass voltage to a third word line. The first pass voltage may be less than the first program voltage, and the first pass voltage is less than the second program voltage.

In some implementations, the method may include applying a verify voltage to the first word line. In some implementations, the method may include applying a second pass voltage to the second word line and the third word line during a verify phase of the first program loop.

In some implementations, the first preset value may range from 5V to 7V.

In some implementations, the first program voltage may be equal to the second program voltage.

In some implementations, the first word line may be coupled to a plurality of first memory cells, and the second word line may be coupled to a plurality of second memory cells. In some implementations, for each first memory cell of a plurality of first memory cells in a same memory slice, a threshold voltage of the first memory cell may be greater than a threshold voltage of a second memory cell belonging to a same memory string as the first memory cell, or a threshold voltage of the first memory cell may be less than a threshold voltage of a second memory cell belonging to a same memory string as the first memory cell, or a threshold voltage of the first memory cell may be equal to a threshold voltage of a second memory cell belonging to a same memory string as the first memory cell.

In some implementations, the method may include applying a third program voltage to a fourth word line adjacent to the first word line while applying the first program voltage to the first word line during the program phase of the first program loop. In some implementations, the first word line may be located between the second word line and the fourth word line, and an absolute value of a difference between the first program voltage and the third program voltage may be less than a second preset value.

In some implementations, the second preset value may range from 5V to 7V.

In some implementations, the third program voltage may be equal to the first program voltage, and the second program voltage may be equal to the first program voltage.

In some implementations, the first word line may be coupled to a plurality of first memory cells, and the fourth word line may be coupled to a plurality of third memory cells. In some implementations, for each first memory cell of a plurality of first memory cells in a same memory slice, a threshold voltage of the first memory cell may be greater than a threshold voltage of a third memory cell belonging to a same memory string as the first memory cell, or a threshold voltage of the first memory cell may be less than a threshold voltage of a third memory cell belonging to a same memory string as the first memory cell, or a threshold voltage of the first memory cell may be equal to a threshold voltage of a third memory cell belonging to a same memory string as the first memory cell.

In some implementations, the method may include applying a verify voltage to the first word line. In some implementations, the method may include applying a second pass voltage to the second word line and the third word line. In some implementations, the method may include applying a third pass voltage to the fourth word line during a verify phase of the first program loop.

In some implementations, the method may include applying a fourth program voltage to the first word line while applying a fifth program voltage to the second word line during a program phase of a second program loop after the first program loop. In some implementations, an absolute value of a difference between the fourth program voltage and the fifth program voltage may be less than a third preset value, the first program voltage may be less than the fourth program voltage, the second program voltage may be less than the fifth program voltage, and a difference between the fourth program voltage and the first program voltage may be equal to a difference between the fifth program voltage and the second program voltage.

In some implementations, the method may include applying an input voltage to the first word line. In some implementations, the method may include applying a fourth pass voltage to the second word line during an operation phase with the semiconductor device. In some implementations, the input voltage may correspond to a first element in an input vector or an input matrix.

According to still another aspect of the present disclosure, a computer-readable storage medium storing computer programs thereon is provided. The computer programs, when executed by a processor, performs a method of operating a semiconductor device. The method may include, during a program phase of a first program loop, applying a first program voltage to a first word line and applying a second program voltage to a second word line adjacent to the first word line. An absolute value of a difference between the first program voltage and the second program voltage may be less than a first preset value. The method may include, during the program phase of the first program loop, applying a first pass voltage to a third word line. The first pass voltage may be less than the first program voltage, and the first pass voltage may be less than the second program voltage.

In the examples of the present disclosure, during the program phase of the first program loop, the first program voltage is applied to the first word line while the second program voltage is applied to the second word line adjacent to the first word line, and the absolute value of the difference between the first program voltage and the second program voltage is less than the first preset value. That is, in the examples of the present disclosure, two adjacent word lines are selected at a time, and corresponding program voltages are simultaneously applied to the two word lines to simultaneously perform program operations on the memory cells coupled to the two word lines, and a difference between the program voltages applied to the two word lines is relatively small. Since the difference between the program voltages applied to the two word lines is small, the coupling effect of the two word lines is small, and in addition, since the memory cells coupled to the two word lines are simultaneously programmed and the program voltages applied on the two word lines are close, the threshold voltages of the memory cells coupled to the two word lines are close, results in that the diffusion of electrons of the memory cells coupled to the two word lines along the extending direction of the memory string is weakened, thus the stability of the threshold voltages of the memory cells can be improved, thereby the accuracy of the in-memory computing can be improved.

### BRIEF DESCRIPTION OF THE DRAWINGS

FIG. 1a shows an example schematic structural diagram of a three-dimensional NAND type memory.

FIG. 1b is a schematic diagram of distribution of memory cells of a three-dimensional NAND type memory according to an example of the present disclosure.

FIG. 2 is a schematic diagram of an example memory device including a peripheral circuit according to an example of the present disclosure.

FIG. 3 is a schematic cross-sectional view of a memory array including a memory string according to an example of the present disclosure.

FIG. 4 is a first schematic structural diagram of a semiconductor device according to an example of the present disclosure.

FIG. 5 is a schematic diagram of an example memory device including a memory array and a peripheral circuit according to an example of the present disclosure.

FIG. 6 is a flow chart of a method of operating a semiconductor device according to an example of the present disclosure.

FIG. 7 is a second schematic structural diagram of a semiconductor device according to an example of the present disclosure.

FIG. 8 is a first schematic diagram of voltage application according to an example of the present disclosure.

FIG. 9 is a third schematic structural diagram of a semiconductor device according to an example of the present disclosure.

FIG. 10 is a second schematic diagram of voltage application according to an example of the present disclosure.

FIG. 11 is a fourth schematic structural diagram of a semiconductor device according to an example of the present disclosure.

FIG. 12 is a fifth schematic structural diagram of a semiconductor device according to an example of the present disclosure.

FIG. 13 is a schematic diagram of an example system having a memory system according to an example of the present disclosure.

FIG. 14 is a schematic diagram of an example memory card having a memory system according to an example of the present disclosure.

FIG. 15 is a schematic diagram of an example solid state drive having a memory system according to an example of the present disclosure.

### DETAILED DESCRIPTION

Example implementations disclosed in the present disclosure will be described in more detail below with reference to the accompanying drawings. Although exemplary implementations of the present disclosure are shown in the accompanying drawings, it should be understood that the present disclosure may be implemented in various forms and should not be limited to the implementations set forth herein. Rather, these implementations are provided so that the present disclosure can be more thoroughly understood and the scope disclosed in the present disclosure can be fully conveyed to those skilled in the art.

In the following description, numerous details are present in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, the sizes of layers, regions, elements, and their relative sizes may be exaggerated for clarity. Like reference numbers refer to like elements throughout.

It should be appreciated that when an element or layer is referred to as being “on,” “adjacent to,” “connected to,” or “coupled to” other element or layer, it may be directly on, adjacent to, connected to, or coupled to other element or layer, or there may be intervening element or layer. Conversely, when an element is referred to as being “directly on,” “directly adjacent,” “directly connected to,” or “directly coupled to” other element or layer, there is no intervening element or layer. It should be appreciated that although the terms first, second, third, etc. may be used to describe various elements, components, regions, layers, and/or portions, these elements, components, regions, layers, and/or portions should not be limited by these terms. These terms are used merely to distinguish one element, component, region, layer, or portion from another element, component, region, layer, or portion. Thus, the first element, component, region, layer, or portion discussed below may be represented as a second element, component, region, layer, or portion without departing from the teachings of the present disclosure. When the second element, component, region, layer, or portion is discussed, it is not intended that the present disclosure necessarily includes a first element, component, region, layer, or portion.

For ease of description, spatial relation terms such as “beneath,” “below,” “lower,” “under”, “above,” “upper,” etc., may be employed herein to describe the relationship between one element or feature and other elements or features shown in the figures. It should be appreciated that, in addition to the orientations shown in the figures, the spatial-relation terms intent to further include different orientations of the devices in use and operation. For example, if the devices in the figures are flipped, then elements or features described as “below” or “under” or “beneath” other elements or features will be oriented “on” the other elements or features. Thus, the example terms “below” and “beneath” may include both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, “a”, “an” and “said/the” in the singular form are intended to include the plural forms as well, unless the context indicated clearly otherwise. It should also be understood that the terms at least one of “consists of” or “including”, when used in this description, identify the presence of at least one of stated features, integers, steps, operations, elements or components, but do not exclude the presence and addition of at least one of one or more other features, integers, steps, operations, elements, components or groups. As used herein, the term “at least one of” includes any and all combinations of the related listed items.

For a more detailed understanding of the features and technical contents of the examples of the present disclosure, the implementations of the examples of the present disclosure are described in detail below with reference to the accompanying drawings, and the accompanying drawings are for illustrative purposes only and are not intended to limit the examples of the present disclosure.

In the classic Von Neumann's computing architecture, the memory device is separate from the processor, and the data is transferred between the memory device and the processor through the data bus. When executing the command, the processor first reads the data from the memory device, and then writes the updated data back into the memory device after the processing is complete, and the frequent data migration leads to huge power consumption and time overheads; in addition, due to the limited memory bandwidth, the processing speed of the processor is limited by the access speed of the memory, which greatly affects the calculation performance. With the rise of applications such as big data and artificial intelligence, the processing of massive data has made the bottleneck of Von Neumann's computing architecture increasingly prominent. In order to solve the bottleneck of the classic Von Neumann's computing architecture, the computing-in-memory chip architecture emerges by embedding a calculation function in the memory device. The basic idea is to directly use the memory device to perform logic calculation, thereby reducing the amount of data transmission and the transmission distance between the memory device and the processor, reducing the power consumption while improving the calculation performance, so that a computing system with high computing power, high bandwidth and high energy efficiency is expected to be constructed.

The computing-in-memory chip relies on its own physical properties while having both memory and computing capabilities. The memory capability refers to the ability of different memory devices to store values by changing their conductance values according to their physical properties, and the computing capability refers to the ability to complete the calculation of a vector-matrix multiplication within a certain time according to Ohm's law and Kirchhoff's law by constructing an array composed of memory devices. The computing-in-memory chip includes, but is not limited to, a static random access memory (SRAM), a NAND flash memory, and a dynamic random access memory (DRAM). NAND flash memory is a non-volatile memory and has a large capacity, thus becoming a widely studied object in the computing-in-memory chip. In the following, related contents of the NAND flash memory device are introduced first.

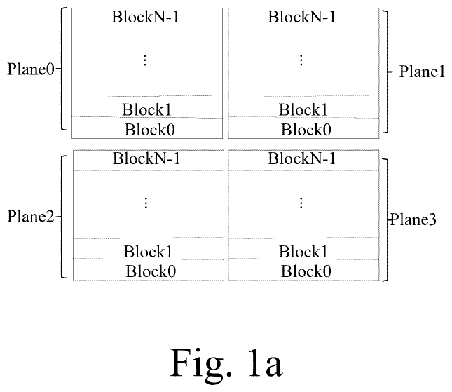

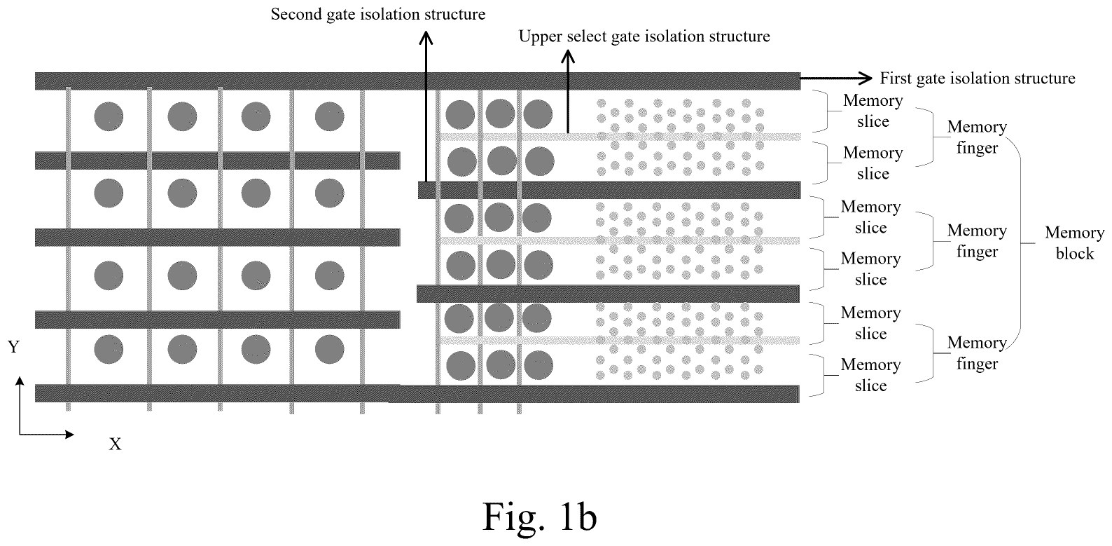

FIG. 1a shows an example schematic structural diagram of a three-dimensional NAND type memory device. FIG. 1b shows an example schematic structural diagram of a memory array of a three-dimensional NAND type memory device. The three-dimensional NAND type memory device includes a memory array and peripheral circuit coupled to the memory array.

As shown in FIG. 1a, the memory array may include a plurality of memory planes, for example, a total of 4 memory planes, Plane0, Plane1, Plane2, and Plane3, and each memory plane includes a plurality of memory blocks.

As shown in FIG. 1b, a memory array of a three-dimensional NAND type memory device is composed of a number of memory cell rows parallel to each other and parallel to the gate isolation structure, each four of memory cell rows are separated by a gate isolation structure and an upper select gate isolation structure, and each memory cell row includes a plurality of memory cells.

The gate isolation structure may include a first gate isolation structure and a second gate isolation structure, the first gate isolation structure divides the memory array into a plurality of memory blocks, the plurality of second gate isolation structures may divide the memory block into a plurality of memory fingers, and an upper select gate isolation structure disposed in the middle of each memory finger may divide the memory finger into two portions, thereby dividing the memory finger into two memory slices.

One memory block shown in FIG. 1b includes 6 memory slices, and in actual application, the number of memory slices in one memory block is not limited thereto.

Only one example memory block of the memory device is shown in FIG. 1b, however, the memory device includes a plurality of memory blocks as shown in FIG. 1b, adjacent memory blocks are separated by the first gate isolation structure, and the plurality of memory blocks may be arranged along the Y-axis direction.

It should be noted that the number of memory cell rows between the gate isolation structure and the upper select gate isolation structure shown in FIG. 1b is merely an example, and is not intended to limit the number of memory cell rows included in one memory finger of the three-dimensional NAND type memory in the present disclosure. In actual applications, the number of memory cell rows included in one memory finger may be adjusted according to actual conditions, such as 2, 4, 8, 16, etc.

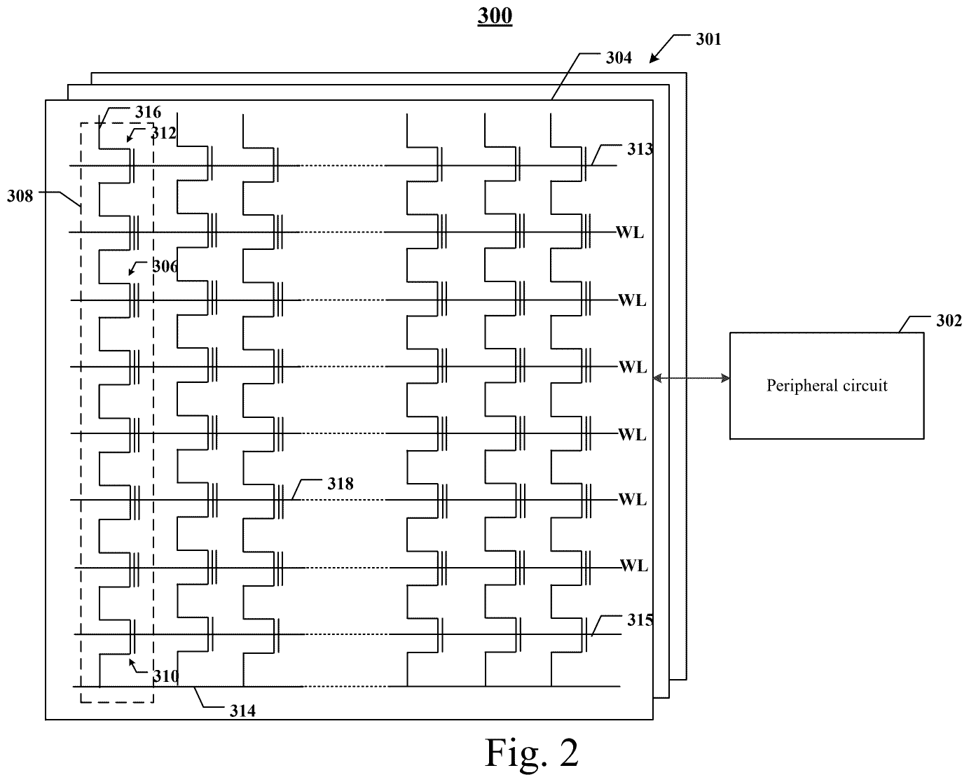

FIG. 2 shows a schematic circuit diagram of an example memory apparatus 300 including a peripheral circuit according to some aspects of the present disclosure.

Referring to FIG. 2, the memory apparatus 300 may include a memory array 301 and a peripheral circuit 302 coupled to the memory array 301. Taking the memory array 301 being a three-dimensional NAND type memory array as an example, where the memory cell 306 is a NAND memory cell, the memory cell 306 is provided in the form of an array of memory strings 308, and each memory string 308 extends vertically above a substrate (not shown). In some implementations, each memory string 308 includes a plurality of memory cells 306 coupled in series and stacked vertically. Each memory cell 306 may maintain a continuous analog value, e.g., voltage or charge, depending on the number of electrons captured within the area of the memory cell 306. Each memory cell 306 may be a floating gate type memory cell including a floating gate transistor, or a charge trapping type memory cell including a charge trapping transistor.

In some implementations, each memory cell 306 is a single level cell (SLC) with two possible memory states and thus may store one bit of data. For example, the first memory state “0” may correspond to a first voltage range and the second memory state “1” may correspond to a second voltage range.

In some implementations, each memory cell 306 is a multi-level cell (MLC) capable of storing more than a single bit of data in more than four memory states. For example, an MLC may store two bits per cell, three bits per cell (also referred to as triple-level cell (TLC)), or four bits per cell (also referred to as quad-level cell (QLC)). Each MLC may be programmed to assume a range of possible nominal stored values. In one example, if each MLC stores two bits of data, the MLC may be programmed to apply one of three possible program levels from an erased state by writing one of three possible nominal stored values to the cell. The fourth nominal stored value may be used for the erased state.

As shown in FIG. 2, each memory string 308 may include a bottom selected transistor (BST) 310 at its source terminal and a top selected transistor (TST) 312 at its drain terminal. The BST 310 and the TST 312 may be configured to activate the selected memory string 308 during read and program operations. In some implementations, the sources of the memory strings 308 in the same memory block 304 are coupled through the same source line (SL) 314 (e.g., common SL). In other words, according to some implementations, all memory strings 308 in the same memory block 304 have an array common source (ACS). According to some implementations, the TST 312 of each memory string 308 is coupled to a respective bit line (BL) 316 from or to which data may be read or written via an output bus (not shown). In some implementations, each memory string 308 is configured to be selected or deselected by applying a pass voltage (e.g., higher than a threshold voltage of a transistor having a TST 312) or a deselect voltage (e.g., OV) to a respective TST 312 via one or more top selected lines (TSLs) 313 and/or by applying a select voltage (e.g., higher than a threshold voltage of a transistor having a BST 310) or a deselect voltage (e.g., OV) to a respective BST 310 via one or more bottom selected lines (BSLs) 315.

As shown in FIG. 2, the memory string 308 may be organized into a plurality of memory blocks 304, each of which may have a common source line 314 (e.g., coupled to ground). In some implementations, each memory block 304 is a basic data unit for an erase operation, e.g., all memory cells 306 on the same memory block 304 are erased simultaneously. To erase the memory cells 306 in the selected memory block, the source line 314 coupled to the selected memory block and unselected memory blocks in the same plane as the selected memory block may be biased with erase voltages (Vers) (e.g., a high positive voltage (e.g., 20V or higher)). It should be understood that in some examples, the erase operation may be performed at a half-memory block level, at a quarter-memory block level, or at a level with any suitable number of memory blocks or any suitable fraction of a memory block. Memory cells 306 of adjacent memory strings 308 may be coupled by word lines 318 that select which row of memory cells 306 is affected by read and program operations.

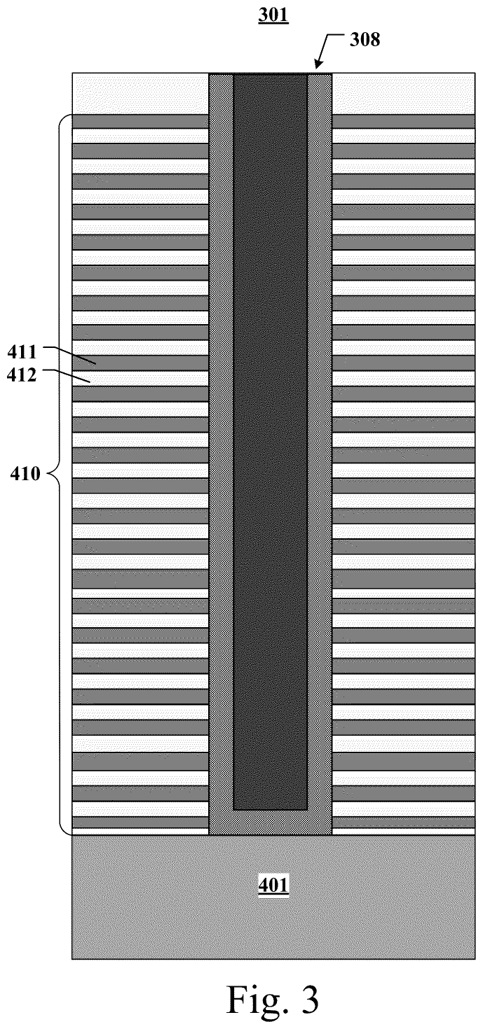

FIG. 3 illustrates a cross-sectional schematic diagram of an example memory array 301 including a memory string 308 according to some aspects of the present disclosure. As shown in FIG. 3, the stacked structure 410 includes a plurality of gate layers 411 and a plurality of insulating layers 412 stacked alternately, and a memory string 308 vertically penetrating through the gate layers 411 and the insulating layers 412. The gate layers 411 and the insulating layers 412 may be stacked alternately, and two adjacent gate layers 411 are separated by an insulating layer 412. The number of memory cells included in the memory array 301 is mainly related to the number of pairs of the gate layer 411 and the insulating layer 412 in the stacked structure 410.

The composition material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, such as a tungsten layer. In some implementations, each gate layer 411 includes a doped polysilicon layer. Each gate layer 411 may include a control gate surrounding the memory cell. The gate layer 411 at the top of the stacked structure 410 may extend laterally as an upper select gate line, the gate layer 411 at the bottom of the stacked structure 410 may extend laterally as a lower select gate line, and the gate layer 411 extending laterally between the upper select gate line and the lower select gate line may act as a word line layer.

In some examples, the stacked structure 410 may be disposed on the substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

In some examples, the memory string 308 includes a channel structure that extends vertically through the stacked structure 410. In some implementations, the channel structure includes a channel hole filled with (one or more types of) semiconductor material (e.g., as a semiconductor channel) and (one or more types of) dielectric material (e.g., as a memory film). In some implementations, the semiconductor channel includes silicon, e.g., polysilicon. In some implementations, the memory film includes a composite dielectric layer including a tunneling layer, a memory layer (also referred to as a “charge trapping/memory layer”), and a blocking layer. The channel structure may have a cylindrical shape (e.g., a pillar shape). According to some implementations, the semiconductor channel, the tunneling layer, the memory layer, and the blocking layer are arranged radially from the center of the pillar toward the outer surface of the pillar in this order. The tunneling layer may include silicon oxide, silicon oxynitride, or any combination thereof. The memory layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

Referring back to FIG. 2, the peripheral circuit 302 may be coupled to the memory array 301 through the bit line 316, the word line 318, the source line 314, the BSL 315, and the TSL 313. The peripheral circuit 302 may include any suitable analog, digital, and mixed-signal circuit for facilitating operation of the memory array 301 by applying voltage signals and/or current signals to and sensing voltage signals and/or current signals from each of the target memory cells 306 via the bit line 316, the word line 318, the source line 314, the BSL 315, and the TSL 313. The peripheral circuit 302 may include various types of peripheral circuit formed using metal-oxide-semiconductor technology.

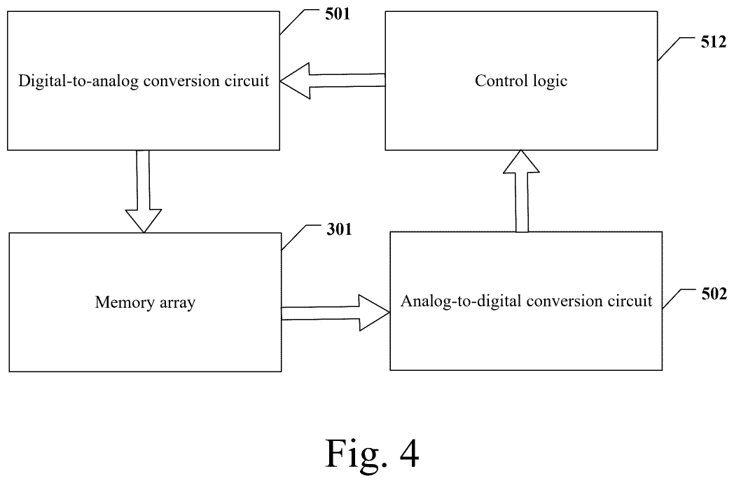

FIG. 4 illustrates some example semiconductor devices, where the peripheral circuit includes the control logic 512, the digital-to-analog conversion circuit 501 coupled to the control logic 512 and the memory array 301, and the analog-to-digital conversion circuit 502 coupled to the memory array 301 and the control logic 512.

During the calculation phase with the semiconductor device, the digital-to-analog conversion circuit 501 may convert the digital signal into a voltage signal required by the memory array 301 in the computing-in-memory chip. The analog-to-digital conversion circuit 502 may convert the current signal output by the memory array 301 into a digital signal. The control logic 512 may be coupled to the peripheral circuit and configured to control operation of the peripheral circuit. The control logic 512 may be further configured to receive input data sent by the memory controller, and send the operation result to the memory controller.

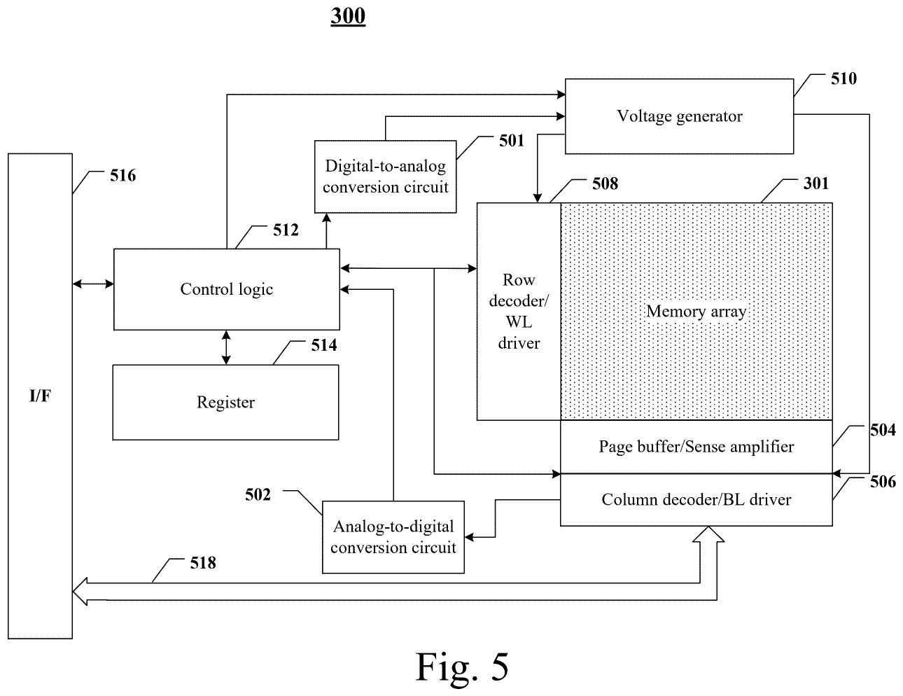

FIG. 5 illustrates some example peripheral circuits, in addition to the structure of the peripheral circuit shown in FIG. 4, the peripheral circuit 302 may also include a page buffer/sense amplifier 504, a column decoder/bit line driver 506, a row decoder/word line driver 508, a voltage generator 510, a control logic 512, a register 514, an interface 516, and a data bus 518. It should be understood that in some examples, additional peripheral circuits not shown in FIG. 4 and FIG. 5 may also be included.

The page buffer/sense amplifier 504 may be configured to read data from and program (write) data to the memory array 301 according to the control signals from the control logic 512. In one example, the page buffer/sense amplifier 504 may store a page of program data (write data) to be programmed into one page of the memory array 301. In another example, the page buffer/sense amplifier 504 may perform a program verify operation to ensure that the data has been properly programmed into the memory cell 306 coupled to the selected word line 318. In yet another example, the page buffer/sense amplifier 504 may also sense, from the bit line 316, a low power signal representing a data bit stored in the memory cell 306, and amplify the small voltage swing to an identifiable logic level in a read operation. The column decoder/bit line driver 506 may be configured to be controlled by the control logic 512 and select one or more memory strings 308 by applying a bit line voltage generated from the voltage generator 510.

The row decoder/word line driver 508 may be configured to be controlled by the control logic 512 and select/deselect the memory block 304 of the memory array 301 and select/deselect the word line 318 of the memory block 304. The row decoder/word line driver 508 may also be configured to drive the word line 318 using the word line voltage generated from the voltage generator 510. In some implementations, the row decoder/word line driver 508 may also select/deselect and drive BSL315 and TSL313. As described in detail below, the row decoder/word line driver 508 is configured to perform a program operation on the memory cells 306 coupled to the selected word line(s) 318. The voltage generator 510 may be configured to be controlled by the control logic 512 and generate the word line voltage (e.g., read voltage, program voltage, pass voltage, local voltage, verify voltage, etc., input voltages), the bit line voltage, and the source line voltage to be supplied to the memory array 301.

The register 514 may be coupled to the control logic 512 and include a status register, a command register, and an address register for storing status information, command operation code (OP code), and command address for controlling operation of each peripheral circuit. The interface 516 may be coupled to the control logic 512 and act as a control buffer to buffer the control command received from a host-side device (not shown) and relay the control command to the control logic 512, and to buffer the status information received from the control logic 512 and relay it to the host-side device. The interface 516 may also be coupled to the column decoder/bit line driver 506 via a data bus 518 and act as a data I/O interface and a data buffer to buffer data and relay it to the memory array 301 or relay or buffer data from the memory array 301.

In some examples, as shown in FIG. 5, the digital-to-analog conversion circuit 501 may be connected to the control logic 512 and the voltage generator 510, and the analog-to-digital conversion circuit 502 may be connected to the control logic 512 and the column decoder/BL driver 506. In the operation phase with the three-dimensional NAND type memory, the control logic may receive input data sent by the memory controller, the digital-to-analog conversion circuit converts the input data to a voltage signal required to be applied on the word line or bit line, the voltage generator generates a corresponding voltage required to be applied on the word line or the bit line, the row decoder/word line driver is configured to drive the selected word line using the word line voltage generated from the voltage generator, or the column decoder/bit line driver is configured to drive the selected bit line using the bit line voltage generated from the voltage generator. The analog operation result obtained by the operation is transmitted to the analog-to-digital conversion circuit through the page buffer and the column decoder, the analog operation result is converted into a digital operation result through the analog-to-digital conversion circuit, and the final digital operation result is transmitted to the control logic.

In some examples, during the computation phase using NAND flash memory as a computing-in-memory chip, before the operation starts, a corresponding program operation may be performed on the memory cells in the memory array to adjust the threshold voltages of the memory cells, so that the weight elements of the weight matrix are written into the memory array according to a certain mapping rule. In some examples, the above mapping rule involves writing each weight element in the weight matrix into the corresponding memory cell in a plurality of memory cells coupled to a selected word line in the memory array. In some other examples, the mapping rule involves writing each weight element in the weight matrix into the corresponding memory cell in a plurality of memory cells of the memory array coupled to a plurality of selected word lines. During the program operation on the memory array and after the program operation is performed on the memory array, the threshold voltages of the memory cells drift, which affects the weight, thereby affecting the performance of the computing-in-memory. How to improve the stability of the threshold voltage of the memory cell and improve the accuracy of the weight becomes an urgent problem to be solved.

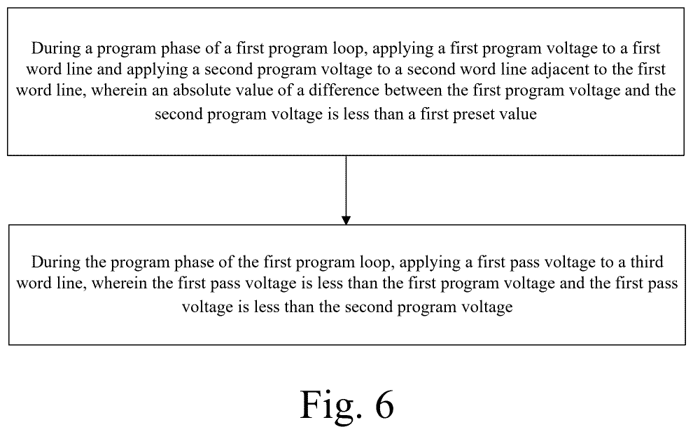

The example of the present disclosure provides a method of operating a semiconductor device. For example, as shown in FIG. 6, the method of operating includes: during a program phase of a first program loop, applying a first program voltage to a first word line and applying a second program voltage to a second word line adjacent to the first word line, where an absolute value of a difference between the first program voltage and the second program voltage is less than a first preset value; and during the program phase of the first program loop, applying a first pass voltage to a third word line, where the first pass voltage is less than the first program voltage and the first pass voltage is less than the second program voltage.

The semiconductor device herein is a computing-in-memory device having storage capabilities and computing capabilities.

Before the operation starts, a corresponding program operation may be performed on the memory cell, a corresponding program voltage is applied to the word line coupled to the memory cell of the memory array, so that the threshold voltage of the memory cell is adjusted, where different threshold voltages may represent different memory states, so that each memory cell stores corresponding data, and the threshold voltage of each memory cell corresponds to one weight element in the weight matrix.

The memory cell in the examples of the present disclosure may be configured to store at least one bit of data, for example, the memory cell in the examples of the present disclosure may be an SLC configured to store one bit of data, or an MLC configured to store two bits of data, or a TLC configured to store three bits of data, or a QLC configured to store four bits of data, or may even be configured to store more bits of data.

Here, the first word line and the second word line are both selected word lines, and the third word line is an unselected word line. In some examples, the third word line may be any one of the word lines other than the first word line and the second word line; that is, in one program operation, there are only two selected word lines, and the other word lines are unselected word lines. In some other examples, in one program operation, there may be three selected word lines, and the third word line may be any one of part of the word lines other than the first word line and the second word line. In the following, a case where there are only two selected word lines and the third word line may be any word line of all word lines other than the first word line and the second word line in one program operation is taken as an example for further illustration.

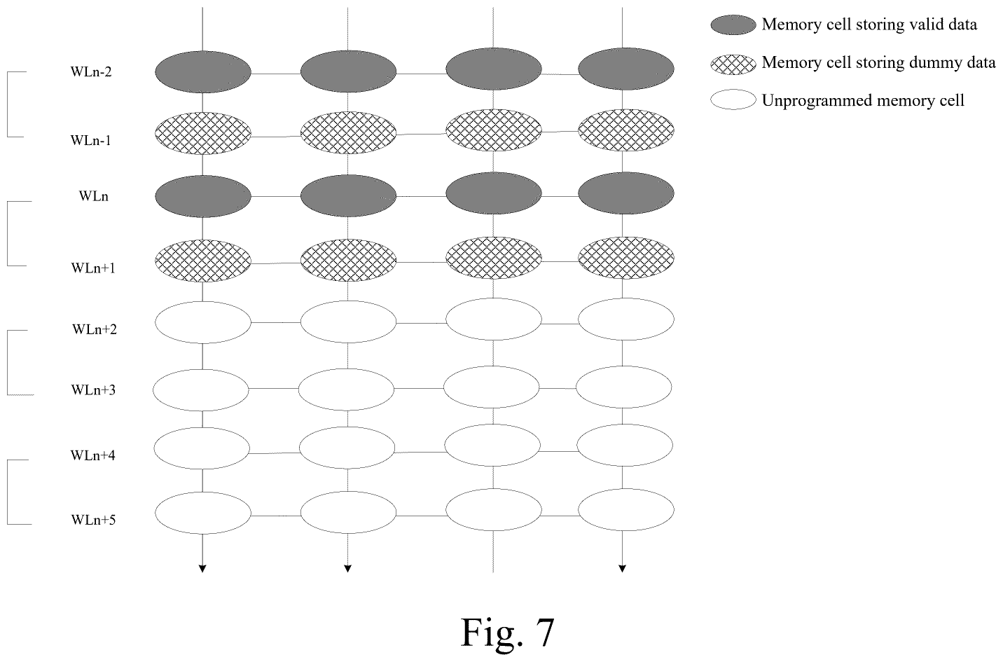

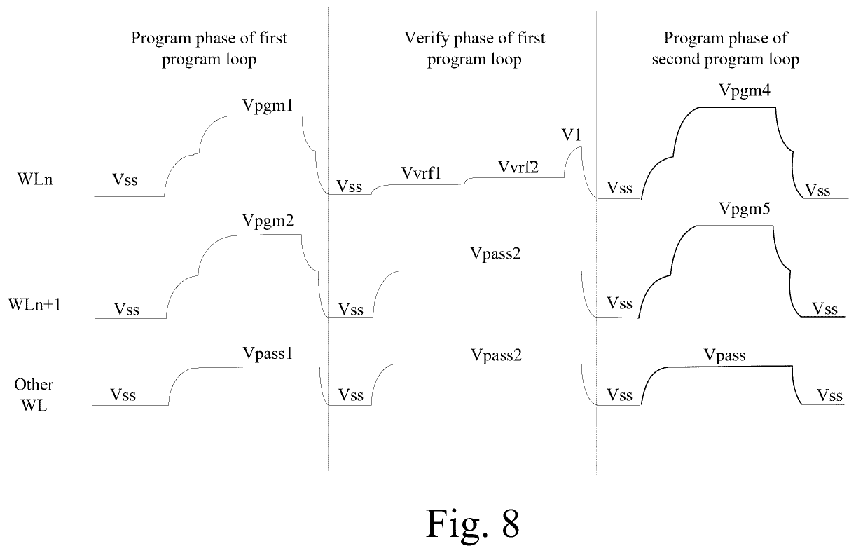

As shown in FIG. 7 and FIG. 8, programming from top to bottom is depicted as an example. WLn−2 and WLn−1 are word lines coupled to the programmed memory cells. WLn and WLn+1 are selected word lines; that is, word lines coupled to the target memory cells, WLn may be the first word line in the above example, and WLn+1 may be the second word line in the above example. WLn+2, WLn+3, WLn+4, and WLn+5 are word lines coupled to the unprogrammed memory cells. The third word line in the above example is an unselected word line, which may be any one of the word lines other than the first word line and the second word line, which is represented by Other WL in FIG. 8. During the program phase of the first program loop, a first program voltage Vpgm1 is applied to the first word line WLn while a second program voltage Vpgm2 is applied to the second word line WLn+1 adjacent to the first word line WLn, and during the program phase of the first program loop, a first pass voltage Vpass1 is applied to the third word line Other WL.

In the example of the present disclosure, during the program phase of the first program loop, the first program voltage is applied to the first word line while the second program voltage is applied to the second word line adjacent to the first word line, and the absolute value of a difference between the first program voltage and the second program voltage is less than a first preset value. That is, in the examples of the present disclosure, two adjacent word lines are selected at a time, and corresponding program voltages are simultaneously applied to the two word lines to simultaneously perform program operations on the memory cells coupled to the two word lines, and the difference between the program voltages applied to the two word lines is relatively small. Since the difference between the program voltages applied to the two word lines is relatively small, the coupling effect of the two word lines is relatively small, and in addition, since the memory cells coupled to the two word lines are simultaneously programmed and the program voltages applied on the two word lines are close, the threshold voltages of the memory cells coupled to the two word lines are close, results in that the diffusion of electrons of the memory cells coupled to the two word lines along the extending direction of the memory string is weakened, thus the stability of the threshold voltages of the memory cells can be improved, the data retention property of the memory cells can be improved, thereby the accuracy of the in-memory computing can be improved.

In some examples, the first preset value ranges from 5V to 7V.

It should be noted that the range of the first preset value provided in the above example is merely an example, and is not intended to limit the range of the first preset value in the example of the present disclosure.

In some examples, the first program voltage is equal to the second program voltage.

It can be understood that when the first program voltage and the second program voltage are equal, the difference between the threshold voltage of the memory cell coupled to the first word line and the threshold voltage of the memory cell coupled to the second word line on the same memory string is smaller, so that the coupling effect between the first word line and the second word line is weaker, and the lateral diffusion effect of electrons of the memory cell coupled to the second word line and the memory cell coupled to the first word line is weaker; thus, the drift of the threshold voltage is smaller, so that the accuracy of in-memory computing is higher.

In some examples, the first word line is coupled to a plurality of first memory cells, and the second word line is coupled to a plurality of second memory cells; and where for each first memory cell of a plurality of first memory cells in a same memory slice, a threshold voltage of the first memory cell is greater than a threshold voltage of a second memory cell belonging to a same memory string as the first memory cell, or a threshold voltage of the first memory cell is less than a threshold voltage of the second memory cell belonging to a same memory string as the first memory cell, or a threshold voltage of the first memory cell is equal to a threshold voltage of the second memory cell belonging to a same memory string as the first memory cell.

In the examples of the present disclosure, for each first memory cell of the plurality of first memory cells, the threshold voltage of the first memory cell being greater than the threshold voltage of the second memory cell belonging to the same memory string as the first memory cell may be understood as: the threshold voltage of the first memory cell being greater than the threshold voltage of the second memory cell in the plurality of memory cells of the same memory string, and the threshold voltage of the first memory cell being greater than the threshold voltage of the second memory cell for each memory string. Likewise, for each first memory cell of the plurality of first memory cells, the threshold voltage of the first memory cell being less than the threshold voltage of the second memory cell belonging to the same memory string as the first memory cell may be understood as: the threshold voltage of the first memory cell being less than the threshold voltage of the second memory cell in the plurality of memory cells of the same memory string, and the threshold voltage of the first memory cell being less than the threshold voltage of the second memory cell for each memory string. Likewise, for each first memory cell of the plurality of first memory cells, the threshold voltage of the first memory cell being equal to the threshold voltage of the second memory cell belonging to the same memory string as the first memory cell may be understood as: the threshold voltage of the first memory cell being equal to the threshold voltage of the second memory cell in the plurality of memory cells of the same memory string, and the threshold voltage of the first memory cell being equal to the threshold voltage of the second memory cell for each memory string.

It may be understood that, as shown in FIG. 1b, the memory array may include a plurality of memory blocks, each memory block includes a plurality of memory fingers, and each memory finger includes a plurality of memory slices. During the program operation on the memory array, different memory slices are programmed separately, and in an incremental step pulse programming (ISPP) operation, only the memory cells in one memory slice coupled to the two word lines are programmed; and during the program operation of the memory cells in one memory slice coupled to the two word lines, in different program loops, the magnitudes of the program voltage applied to the first word line and the second word line have the same trend, so that the threshold voltages of one of the plurality of first memory cells and one of the plurality of second memory cells belonging to the same memory string in the same memory slice have the same trend as described in the above examples.

In the examples of the present disclosure, corresponding program voltages are applied to the first word line and the second word line simultaneously, and the memory cells coupled to the first word line and the memory cells coupled to the second word line are programmed simultaneously. When the first program voltage is greater than the second program voltage, for each first memory cell of a plurality of first memory cells, a threshold voltage of the first memory cell is greater than a threshold voltage of the second memory cell belonging to a same memory string as the first memory cell. When the first program voltage is less than the second program voltage, for each first memory cell of a plurality of first memory cells, a threshold voltage of the first memory cell is less than a threshold voltage of the second memory cell belonging to a same memory string as the first memory cell. When the first program voltage is equal to the second program voltage, for each first memory cell of a plurality of first memory cells, a threshold voltage of the first memory cell is equal to a threshold voltage of the second memory cell belonging to a same memory string as the first memory cell.

In an ISPP program approach, the entire program process can include a plurality of program loops, e.g., a first program loop, a second program loop, . . . , and an N-th program loop. In some examples, each program loop may include a plurality of phases, for example, a program loop may include a program phase and a verify phase. During the verify phase, a program verify operation needs to be performed, in an example, a verify voltage may be applied to a word line coupled to a memory cell that needs to be verified, and a corresponding pass voltage is applied to word lines coupled to other memory cells. During the program phase, the program voltage is applied to the selected word line primarily, the process of applying the program voltage may be that applying a program start voltage first, and then incrementing by a step voltage, and a program-inhibit voltage may be applied to the bit line coupled to the memory cell coupled to the unselected word lines during the program phase.

In an example of the present disclosure, the first program loop may be any program loop in the entire program process. In some examples, the first program loop may be the first program loop in the entire ISPP program operation, and the program voltage applied in the first program loop is the start program voltage. In other examples, the first program loop may also be a program loop in the middle, and there may be other program loops before the first program loop. In some examples, the first program loop may also be the last program loop. In the following, a case where the first program loop is the first program loop of the entire program process or the program loop in the middle of the entire program process is taken as an example for further illustration.

In some examples, as shown in FIG. 8, the method of operating further includes: applying a fourth program voltage Vpgm4 to the first word line WLn while applying a fifth program voltage Vpgm5 to the second word line WLn+1 during a program phase of a second program loop after the first program loop, where an absolute value of a difference between the fourth program voltage Vpgm4 and the fifth program voltage Vpgm5 is less than a third preset value, the first program voltage is less than the fourth program voltage, the second program voltage is less than the fifth program voltage, and a difference between the fourth program voltage and the first program voltage is equal to a difference between the fifth program voltage and the second program voltage.

The program voltage applied to the same word line in the second program loop herein is the program voltage applied to the word line in the first program loop plus a fixed step voltage, and the step voltages added for the first word line and the second word line are equal. Since the difference between the first program voltage applied on the first word line and the second program voltage applied on the second word line is small, so that the difference between the threshold voltage of the first memory cell and the threshold voltage of the second memory cell on the same memory string after the first program loop is small; and when the program voltage applied to the same word line in the second program loop is the program voltage applied to the word line in the first program loop plus the fixed step voltage, and the step voltages added for the first word line and the second word line are equal, the difference between the program voltage applied to the first word line and the program voltage applied to the second word line in the second program loop is still small, so that after the second program loop, the difference between the threshold voltage of the first memory cell and the threshold voltage of the second memory cell on the same memory string still keeps small. Cases are similar for other program loops, so that after the programming of the memory cell coupled to the first word line and the memory cell coupled to the second word line through the ISPP program operation, the difference between the threshold voltage of the first memory cell and the threshold voltage of the second memory cell on the same memory string always keeps at a relatively small level, thereby further improving the stability of the threshold voltage of the memory cell and improving the accuracy of in-memory computing.

In the examples of the present disclosure, corresponding program voltages are applied to the first word line and the second word line simultaneously, and in the ISPP program approach, the magnitude of the step voltage is fixed; that is, in different program loops, the magnitude of the program voltage applied to the first word line and the magnitude of the program voltage applied to the second word line have the same trend. For example, the first program loop is the first program loop of the entire program process or the program loop in the middle of the entire program process; when the first program voltage applied to the first word line in the first program loop is greater than the second program voltage applied to the second word line in the first program loop, the program voltage in each of the subsequent program loops is the program voltage of the previous program loop plus the fixed step voltage, and the corresponding step voltages added for the first word line and the second word line are equal; thus, the program voltage applied to the first word line is greater than the program voltage applied to the second word line in each program loop.

Likewise, when the first program loop is the first program loop of the entire program process or the program loop in the middle of the entire program process, and when the first program voltage applied to the first word line in the first program loop is less than the second program voltage applied to the second word line in the first program loop, the program voltage applied to the first word line is less than the program voltage applied to the second word line in each program loop. Likewise, when the first program loop is the first program loop of the entire program process or the program loop in the middle of the entire program process, and when the first program voltage applied to the first word line in the first program loop is equal to the second program voltage applied to the second word line in the first program loop, the program voltage applied to the first word line is equal to the program voltage applied to the second word line in each program loop.

It can be understood that, in different program loops, the magnitude of the program voltage applied to the first word line and the magnitude of the program voltage applied to the second word line have the same trend, so that the magnitude of the threshold voltage of the first memory cell and the magnitude of the threshold voltage of the second memory cell on the same memory string have consistent trend. For example, when the first program voltage is greater than the second program voltage, for each first memory cell of a plurality of first memory cells, a threshold voltage of the first memory cell is greater than the threshold voltage of the second memory cell belonging to the same memory string as the first memory cell. For example, when the first program voltage is less than the second program voltage, for each first memory cell of a plurality of first memory cells, a threshold voltage of the first memory cell is less than the threshold voltage of the second memory cell belonging to the same memory string as the first memory cell. For example, when the first program voltage is equal to the second program voltage, for each first memory cell of a plurality of first memory cells, a threshold voltage of the first memory cell is equal to the threshold voltage of the second memory cell belonging to the same memory string as the first memory cell.

It should be noted that, in the description of the trend of the magnitude of the threshold voltage of the first memory cell and the magnitude of the threshold voltage of the second memory cell belonging to the same memory string as the first memory cell for each first memory cell of the plurality of first memory cells in the above examples, the above examples do not take the influence on the threshold voltage of the memory cell caused by the inconsistent program speeds of the first memory cell and the second memory cell on the same memory string due to the process cause into consideration.

Moreover, even if the inconsistent program speeds of the first memory cell and the second memory cell on the same memory string due to the process cause is taken into consideration, the influence of the difference of the program speeds due to the process cause on the threshold voltage of the memory cell is limited; thus, when programming with the ISPP program approach, the program voltage is gradually increased, and the influence of the program voltage on the threshold voltage is greater than the influence of the process cause on the threshold voltage; thus, the difference due to the process cause can be negligible, and thus, for each first memory cell of a plurality of the first memory cells, the trend of the magnitude of the threshold voltage of the first memory cell and the magnitude of the threshold voltage of the second memory cell belonging to the same memory string as the first memory cell in the above examples still makes sense.

In the examples of the present disclosure, when the memory cells coupled to the first word line and the second word line are programmed simultaneously, and the difference between the program voltage applied to the first word line and the program voltage applied to the second word line is small, the memory state of the first memory cell and the memory state of the second memory cell on the same memory string may be consistent, and different memory states may correspond to different threshold voltage ranges.

In some examples, as shown in FIG. 8, the method of operating further includes: applying a corresponding pass voltage Vpass to the third word line during the program phase of the first program loop.

The pass voltage Vpass herein may be equal to at least one of the first pass voltage, the second pass voltage, the third pass voltage and the fourth pass voltage in the examples of the present disclosure, or may be different from the first pass voltage, the second pass voltage, the third pass voltage and the fourth pass voltage.

In some examples, as shown in FIG. 8, the method of operating further includes: applying a verify voltage (Vvrf1, Vvrf2) to the first word line WLn and a second pass voltage Vpass2 to the second word line WLn+1 and the third word line Other WL during a verify phase of the first program loop.

In the examples of the present disclosure, after performing the program operation on the memory cells coupled to the first word line and the second word line simultaneously during the program phase of the first program loop, in the verify phase of the first program loop, the verify voltage is applied to only the first word line, and the second pass voltage is applied to the second word line and the third word line That is, during the verify phase of the first program loop, corresponding verify operation is performed on only the memory cell coupled to the first word line, and corresponding verify operation is not performed on the memory cells coupled to the second word line.

It can be understood that, in the examples of the present disclosure, the memory cells coupled to the first word line and the second word line are programmed simultaneously, and the difference between the applied program voltages is small. The difference between the threshold voltage of the memory cell coupled to the first word line and the threshold voltage of the memory cell coupled to the second word line on the same memory string may be considered to be small. Hence, the corresponding verify operation may be performed on only the memory cell coupled to the first word line. In this way, the verify time can be saved, and the efficiency of the whole program operation can be improved.

In some examples, as shown in FIG. 8, the first voltage V1 may also be applied to the first word line WLn in the verify phase to perform corresponding discharge processing on the channel.

In the following, a case where there are three selected word lines and the third word line is any one of the word lines other than the first word line and the second word line in one program operation is taken as an example for further illustration.

In some examples, the method of operating further includes: applying a third program voltage to a fourth word line adjacent to the first word line while applying the first program voltage to the first word line during the program phase of the first program loop, where the first word line is located between the second word line and the fourth word line, and an absolute value of a difference between the first program voltage and the third program voltage is less than a second preset value.

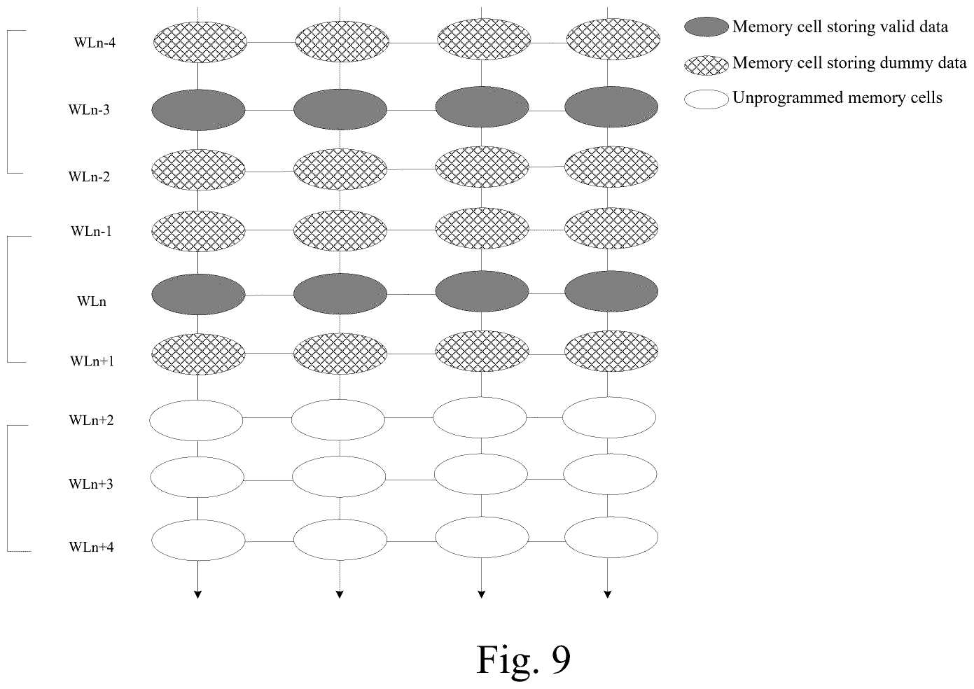

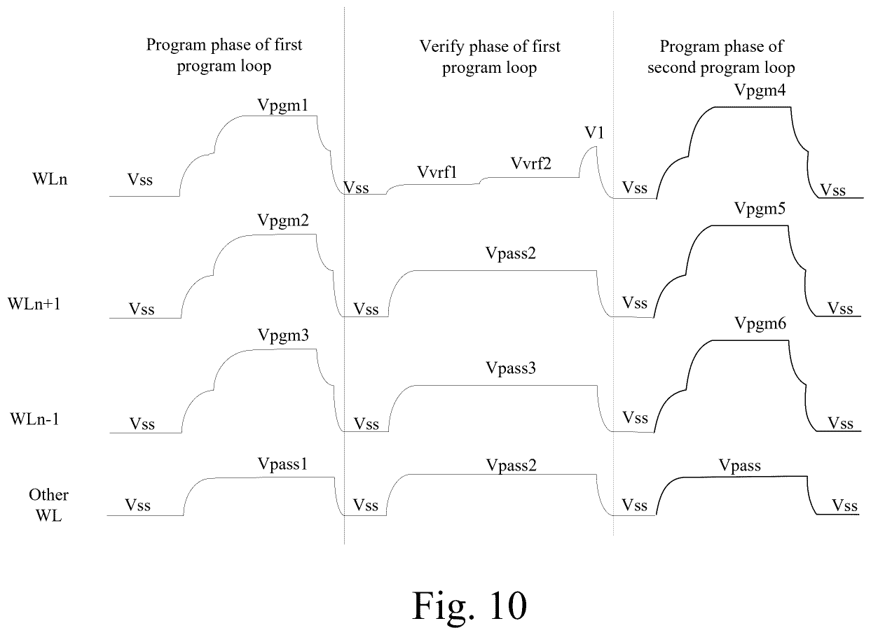

As shown in FIG. 9 and FIG. 10, program from top to bottom is taken as an example. WLn−4, WLn−3, and WLn−2 are word lines coupled to the programmed memory cells. WLn−1, WLn and WLn+1 are selected word lines; that is, word lines coupled to the target memory cell, WLn may be the first word line in the above example, WLn+1 may be the second word line in the above example, and WLn−1 may be the fourth word line in the above example. WLn+2, WLn+3, and WLn+4 are word lines coupled to the unprogrammed memory cells. The third word line in the above example is an unselected word line, which may be any one of the word lines other than the first word line, the second word line, and the fourth word line, which is represented by the Other WL in FIG. 10. During the program phase of the first program loop, a first program voltage Vpgm1 is applied to the first word line WLn, and a second program voltage Vpgm2 is applied to the second word line WLn+1 adjacent to the first word line WLn at the same time, and a third program voltage Vpgm3 is applied to the fourth word line WLn−1 adjacent to the first word line WLn at the same time, and during the program phase of the first program loop, a first pass voltage Vpass1 is applied to the third word line Other WL.

In some examples, the third program voltage is greater than the first pass voltage.

It can be understood that in the above example, during the program phase of the first program loop, the corresponding program voltages are applied to the adjacent first word lines, the second word lines and the fourth word lines at the same time, and the difference between the program voltages applied on the first word line, the second word line and the fourth word line is small. In this way, the memory cell coupled to the first word line are protected by the memory cell coupled to the adjacent second word line and the memory cell coupled to the adjacent fourth word line. Hence, the coupling effects of the first word line and the adjacent second word line and the adjacent fourth word line are relatively weak; the memory cell coupled to the first word line and the memory cell coupled to the second word line and the memory cell coupled to the fourth word line have a weaker electron transverse diffusion effect, thereby further improving the stability of the threshold voltages of the memory cells, and thus further improving the accuracy of in-memory computing.

In some examples, the second preset value ranges from 5V to 7V.

It should be noted that the range of the second preset value according to the above example is merely an example, and is not intended to limit the range of the second preset value in the examples of the present disclosure.

In some examples, the third program voltage is equal to the first program voltage, and the second program voltage is equal to the first program voltage.

It can be understood that, when the first program voltage, the second program voltage, and the third program voltage are equal; the difference between any two of the threshold voltage of the memory cell coupled to the first word line, the threshold voltage of the memory cell coupled to the second word line, and the threshold voltage of the memory cell coupled to the fourth word line on the same memory string is smaller. Thus, the memory cell coupled to the first word line is subject to less coupling effect from the adjacent memory cell on the same memory string, and the effect of the electrons of the memory cell coupled to the first word line diffusing to the adjacent memory cell on the same memory string is weaker. Hence, the drift of the threshold voltage of the memory cell coupled to the first word line is smaller, so that the accuracy of in-memory computing is higher.

In some examples, the first word line is coupled to a plurality of first memory cells, and the fourth word line is coupled to a plurality of third memory cells; for each first memory cell of a plurality of first memory cells in a same memory slice, a threshold voltage of the first memory cell is greater than a threshold voltage of the third memory cell belonging to a same memory string as the first memory cell, or a threshold voltage of the first memory cell is less than a threshold voltage of the third memory cell belonging to a same memory string as the first memory cell, or a threshold voltage of the first memory cell is equal to a threshold voltage of the third memory cell belonging to a same memory string as the first memory cell.

It can be understood that, in different program loops, the magnitude of the program voltage applied to the first word line and the magnitude of the program voltage applied to the fourth word line have the same trend, so that the magnitude of the threshold voltage of the first memory cell and the magnitude of the threshold voltage of the third memory cell on the same memory string have consistent trend.

In some examples, as shown in FIG. 10, the method of operating further includes: applying a verify voltage (Vvrf1, Vvrf2) to the first word line WLn, and applying a second pass voltage Vpass2 to the second word line WLn+1 and the third word line Other WL, and applying a third pass voltage Vpass3 to the fourth word line WLn−1 during the verify phase of the first program loop.

In some examples, the first pass voltage, the second pass voltage, the third pass voltage, and the fourth pass voltage mentioned later may be equal or different.

In the examples of the present disclosure, after the program operation is performed on the memory cells coupled to the first word line, the second word line and the fourth word line simultaneously during the program phase of the first program loop, in the verify phase of the first program loop, the verify voltage is applied to only the first word line, and the corresponding pass voltage is applied to the second word line and the fourth word line, that is, during the verify phase of the first program loop, the corresponding verify operation is performed on only the memory cell coupled to the first word line, and the corresponding verify operation is not performed on the memory cells coupled to the second word line and the fourth word line.

It can be understood that, in the examples of the present disclosure, the memory cells coupled to the first word line, the second word line, and the fourth word line are programmed simultaneously, and the difference between the applied program voltages is small, the difference between two of the threshold voltage of the memory cell coupled to the first word line, the threshold voltage of the memory cell coupled to the second word line, and the threshold voltage of the memory cell coupled to the fourth word line on the same memory string may be considered to be small, so that the corresponding verify operation may be performed on only the memory cell coupled to the first word line, so that the verify time can be further saved, and the efficiency of the whole program operation can be improved.

In the examples of the present disclosure, the plurality of word lines in the memory array may be divided into several groups, and each group may include two word lines as shown in FIG. 7, and each group may also include three word lines as shown in FIG. 9. During programming, programming is performed in groups.

As shown in FIG. 7, each group includes two word lines, for example, WLn−2 and WLn−1 are grouped together, WLn and WLn+1 are grouped together, WLn+2 and WLn+3 are grouped together, and WLn+4 and WLn+5 are grouped together. Corresponding program voltages are applied to two word lines in one group simultaneously in each program loop, and the memory cells coupled to each group are sequentially programmed in the order from top to bottom as shown in FIG. 7.

In the operation phase with the semiconductor device, the memory cells coupled to one of the two word lines in each group store valid data as the weight data that participates in operation, and the memory cells coupled to the other one of the two word lines in each group store dummy data that does not participate in operation. From the perspective of the entire memory array, the word lines coupled to the memory cells storing valid data and the word lines coupled to the memory cells storing dummy data are alternately arranged along the extending direction of the memory strings.

It can be understood that, in the examples of the present disclosure, the plurality of word lines are divided into a plurality of groups, each group includes two adjacent word lines. When the program operations are performed on the memory cells, the program voltages are sequentially applied to the word lines of the plurality of groups, and the program voltages with smaller differences are applied to the two word lines in the same group at the same time. Hence, the difference between the threshold voltages of the memory cells belonging to the same memory string among the plurality of memory cells coupled to the two word lines in the same group is small, and the migration of electrons of the memory cells coupled to the two word lines in the same group along the extending direction of the memory string is weakened. Thus, the stability of the threshold voltage of the memory cell can be improved, the data retention property of the memory cell is improved, and the accuracy of in-memory computing is improved.

In some examples, when each group includes two word lines, if the program order is from top to bottom, the memory cells coupled to the upper word line in the two word lines of each group store valid data that participates in operation, and the memory cells coupled to the lower word line in the two word lines of each group store dummy data that does not participates in operation.

In some examples, in a manner of program from top to bottom as shown in FIG. 7, WLn and WLn+1 are target word lines, memory cells coupled to the word lines below WLn+1 are not programmed, and memory cells coupled to word lines above WLn have been programmed, memory cells coupled to the upper word lines (e.g., WLn−2, WLn) store valid data, and memory cells coupled to lower word lines (e.g., WLn−1, WLn+1) store dummy data.

It can be understood that, when the program operation is performed on the memory cells coupled to WLn+2 after the program operation is completed on the memory cells coupled to WLn and WLn+1, it is required to apply the program voltage to WLn+2 and apply the corresponding pass voltages to WLn and WLn+1, and the difference between the pass voltages applied to WLn and WLn+1 is small, and the difference between the program voltage and the pass voltage is large. Hence, the coupling effect of WLn+1 to WLn is less than the coupling effect of WLn+2 to WLn+1, so that the program disturbance to the memory cells coupled to WLn during the program operation on the memory cells coupled to WLn+2 is small, and the threshold voltage of the memory cells coupled to WLn is more stable than the memory cells coupled to WLn+1. Moreover, the data retention property of the memory cells coupled to the upper word line is improved in each group. Therefore, the memory cells coupled to the upper word line in each group are selected to store valid data and participate in operation to achieve higher accuracy of in-memory computing.

In some examples, the first word line is coupled to a plurality of first memory cells, and the second word line is coupled to a plurality of second memory cells. In a manner of program from top to bottom, if the first word line is located above the second word line, the memory cells coupled to the first word line store valid data, the memory cells coupled to the second word line store dummy data, and in the plurality of first memory cells and the plurality of second memory cells of the same memory slice, the distribution width of the threshold voltages of the first memory cells of the plurality of memory cells in the same memory state is less than the distribution width of the threshold voltages of the second memory cells of the plurality of memory cells.

Taking the SLC as an example, a distribution width of the threshold voltages of a plurality of first memory cells in a programmed state in a same memory slice is smaller than a distribution width of the threshold voltages of a plurality of second memory cells in a programmed state in the memory slice.

It can be understood that, after the program operation is completed on the memory cells coupled to the first word line and the second word line, a corresponding program voltage needs to be applied to a word line (for example, a third word line) adjacent to the second word line and located below the second word line to perform a program operation. In this case, a corresponding pass voltage is applied to both the first word line and the second word line, since the difference between the program voltage and the pass voltage is larger, the coupling effect of the second word line to the first word line is less than the coupling effect of the third word line to the second word line, the stability of the threshold voltages of the memory cells coupled to the first word line is higher. Thus, the distribution width of the threshold voltages of the first memory cells of the plurality of memory cells in the same memory state is smaller than the distribution width of the threshold voltages of the second memory cells.

As shown in FIG. 9, each group includes three word lines, e.g., WLn−4, WLn−3, and WLn−2 are grouped together, WLn−1, WLn, and WLn+1 are grouped together, and WLn+2, WLn+3, and WLn+4 are grouped together.

In each program process, corresponding program voltages are applied to three word lines in one group at the same time, and the program operation is performed on the memory cells coupled to each group sequentially in the order from top to bottom as shown in FIG. 9.

In the operation phase with the semiconductor device, the memory cells coupled to one of the three word lines in each group store valid data as the weight data that participates in operation, and the memory cells coupled to the other two of the three word lines in each group store dummy data that does not participate in operation. In addition, the memory cells coupled to one word line (e.g., WLn) in the middle of the three word lines in each group store valid data, and the memory cells coupled to two word lines (e.g., WLn−1 and WLn+1) on both sides of the three word lines in each group store dummy data.

It can be understood that, in the examples of the present disclosure, the corresponding program voltages are applied to the three word lines of each group at the same time, and the difference between the program voltages is small. Hence, the difference between the threshold voltages of the three memory cells coupled to the three word lines of the same group on the same memory string is small, and the difference between the threshold voltages of the memory cell storing the valid data and two adjacent memory cells storing the dummy data on the same memory string is small. Thus, the two adjacent memory cells storing the dummy data on the memory string protect the memory cell storing the valid data between the two memory cells storing the dummy data, and the stability of the threshold voltages of the memory cells storing the valid data is high. Consequently, the problem of low accuracy of in-memory computing caused by the threshold voltage drift of the memory cell can be improved.

It should be noted that the above examples take the program from top to bottom as an example for illustration only. In some examples, corresponding program operations may also be performed in a program order from bottom to top.

In the examples of the present disclosure, the difference between the threshold voltages of the first memory cell and the second memory cell on the same memory string is small, and the first memory cell and the second memory cell on the same memory string are in the same memory state. Taking the SLC as an example, when the first memory cell on a certain memory string is in an erased state, the second memory cell on the memory string is in an erased state; and when the first memory cell on a certain memory string is in a programmed state, the second memory cell on the memory string is in a programmed state.

In some examples, different elements in the input vector or the input matrix used as input data are converted into input voltages required to be input on different bit lines through the digital-to-analog conversion circuit, and each element in the input vector or the input matrix corresponds to an input voltage required to be input on one bit line. The current output by the source line terminal of the memory array is equivalent to a result of multiplying the input data (corresponding to the input vector or the input matrix) and the valid data stored in the memory cells in the memory array.

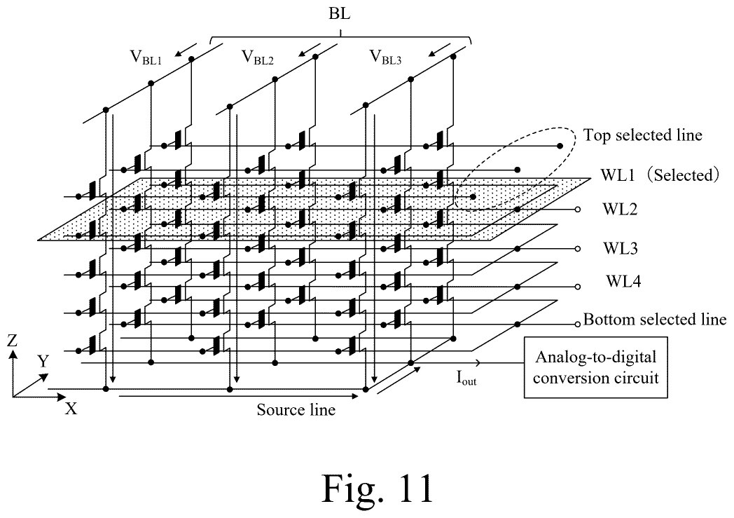

In an example, as shown in FIG. 11, in the in-memory computing manner in which the input voltage is applied from the bit line, before the operation starts, the weight elements in the weight matrix are written into the plurality of memory cells coupled to the selected word line WL1.

After different elements in the input vector or the input matrix are converted into input voltages required to be input on different bit lines through the digital-to-analog conversion circuit, the input voltage (V_{BL1}, V_{BL2}, V_{BL3}) required to be input on each bit line is applied to the corresponding bit line. A result of multiplying or multiplying and adding the input vector or the input matrix and the weight matrix is equivalent to a current Iₒᵤₜ output by the source line terminal, and the analog current signal is converted into a digital signal through an analog-to-digital conversion circuit such as a current-mode analog-to-digital conversion circuit. In this in-memory computing manner, each calculation may select a different word line as the selected word line, but only one word line is selected in each calculation, and the memory cells coupled to the selected word line store valid data. The word line coupled to the memory cells storing the dummy data is the unselected word line that does not participate in operation.

In some examples, different elements in the input vector or the input matrix used as input data are converted into input voltages required to be input on different word lines through the digital-to-analog conversion circuit, and each element in the input vector or the input matrix corresponds to an input voltage required to be applied on one word line. The voltage output by the bit line terminal of the memory array is equivalent to the result of multiplying the input data (corresponding to the input vector or the input matrix) and the valid data stored in the memory array.

In some examples, the method of operating further includes: applying an input voltage to the first word line and applying a fourth pass voltage to the second word line during an operation phase with the semiconductor device, where the input voltage corresponds to a first element in an input vector or an input matrix.

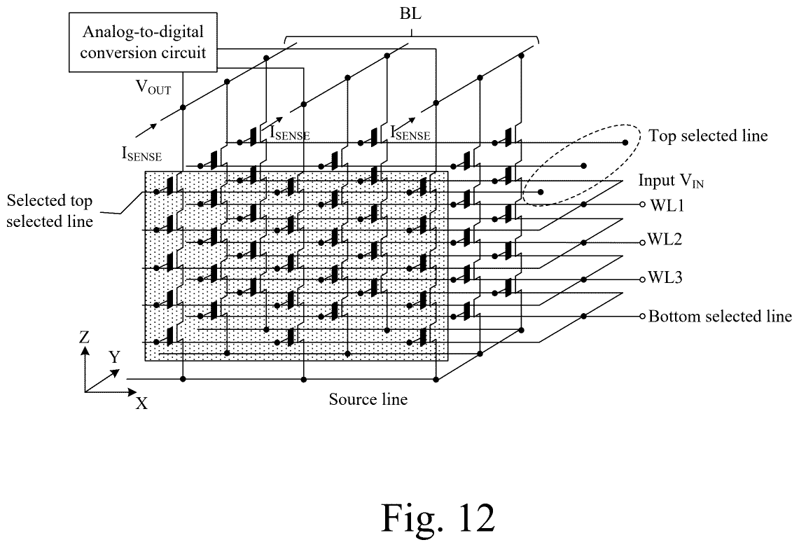

For example, in the in-memory computing manner in which the input voltage is applied from the word line, as shown in FIG. 12, before the operation starts, the weight elements in the weight matrix are written into the plurality of memory cells coupled to the word lines WL1 and WL3.

After different vector elements in the input vector or the input matrix are converted into input voltages Input VIN required to be input on the word lines WL1 and WL3 through the digital-to-analog conversion circuit, input voltages (V_{w11}, V_{w13}) required to be input by the word lines WL1 and WL3 are applied to corresponding word lines. The result of multiplying or multiplying-adding the input vector or the input matrix and the weight matrix is equivalent to the voltage VOUT output by the bit line terminal. The memory cells coupled to the word lines WL1 and WL3 store valid data that participates in operation, while the memory cells coupled to the word lines WL2 store dummy data that does not participate in operation, and the fourth pass voltage is applied to the word line WL2 in the operation process.

For example, in the in-memory computing manner in which the input voltage is applied from the word line, as shown in FIG. 12, an input voltage may also be applied to the word line WL2, while a fourth pass voltage may be applied to the word lines WL1 and WL3, memory cells coupled to the word line WL2 store valid data that participates in operation, and memory cells coupled to the word lines WL1 and WL3 store dummy data that does not participate in operation.

In the examples of the present disclosure, the input vector or the input matrix may be sent to a peripheral circuit of the semiconductor device by a controller coupled to the semiconductor device.

In some examples, the peripheral circuit includes: an analog-to-digital conversion circuit coupled to the memory array and configured to convert an analog signal into a digital signal; and a digital-to-analog conversion circuit coupled to the memory array and configured to convert a digital signal into an analog signal.

In some examples, the digital-to-analog conversion circuit may convert the input data into input voltage information, and the voltage generator in the peripheral circuit generates a corresponding input voltage and applies the input voltage to the corresponding word line or bit line. The peripheral circuit may include one or more analog-to-digital conversion circuits. In the calculation manner in which the input voltage is applied from the bit line as shown in FIG. 11, the analog-to-digital conversion circuit is connected to the source line and is configured to convert the output current on the source line into a digital signal, so as to output an operation result. In the calculation manner in which the input voltage is applied from the word line as shown in FIG. 12, the analog-to-digital conversion circuit is connected to the bit line and is configured to convert the output voltage on the bit line into a digital signal, so as to output an operation result.

Based on the above method of operating the semiconductor device, an example of the present disclosure further provides a computer-readable storage medium storing computer programs that, when executed by a processor, implement the method of operating according to any one of the above examples.

Herein, all or part of the processes in the method of operating in the above examples may be completed by using computer programs to instruct related hardware, and the programs may be stored in a computer-readable storage medium, and the programs, when executed, may include a process of the examples of the above methods. The storage medium may be a ferromagnetic random access memory (FRAM), a read only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM), and the like; and the storage medium may further include a combination of the above types of memories.

Based on the method of operating the semiconductor device, the example of the present disclosure further provides a semiconductor device, including a memory array and a peripheral circuit coupled to the memory array, where the peripheral circuit is configured to: apply a first program voltage to a first word line while applying a second program voltage to a second word line adjacent to the first word line during a program phase of a first program loop, where an absolute value of a difference between the first program voltage and the second program voltage is less than a first preset value; and apply a first pass voltage to a third word line during the program phase of the first program loop, where the first pass voltage is less than the first program voltage and the first pass voltage is less than the second program voltage.

In some examples, the peripheral circuit is configured to: apply a verify voltage to the first word line and a second pass voltage to the second word line and the third word line during a verify phase of the first program loop.

In some examples, the first preset value ranges from 5V to 7V.

In some examples, the first program voltage is equal to the second program voltage.

In some examples, the first word line is coupled to a plurality of first memory cells, and the second word line is coupled to a plurality of second memory cells; and where for each first memory cell of a plurality of first memory cells in a same memory slice, a threshold voltage of the first memory cell is greater than a threshold voltage of the second memory cell belonging to a same memory string as the first memory cell, or a threshold voltage of the first memory cell is less than a threshold voltage of the second memory cell belonging to a same memory string as the first memory cell, or a threshold voltage of the first memory cell is equal to a threshold voltage of the second memory cell belonging to a same memory string as the first memory cell.

In some examples, the peripheral circuit is configured to: apply a third program voltage to a fourth word line adjacent to the first word line while applying the first program voltage to the first word line during the program phase of the first program loop, where the first word line is located between the second word line and the fourth word line, and an absolute value of a difference between the first program voltage and the third program voltage is less than a second preset value.

In some examples, the second preset value ranges from 5V to 7V.

In some examples, the third program voltage is equal to the first program voltage, and the second program voltage is equal to the first program voltage.

In some examples, the first word line is coupled to a plurality of first memory cells, and the fourth word line is coupled to a plurality of third memory cells; for each first memory cell of the plurality of first memory cells in a same memory slice, a threshold voltage of the first memory cell is greater than a threshold voltage of the third memory cell belonging to a same memory string as the first memory cell, or a threshold voltage of the first memory cell is less than a threshold voltage of the third memory cell belonging to a same memory string as the first memory cell, or a threshold voltage of each first memory cell of a plurality of first memory cells in a same memory slice is equal to a threshold voltage of the third memory cell belonging to a same memory string as the first memory cell.

In some examples, the peripheral circuit is configured to: apply a verify voltage to the first word line, apply a second pass voltage to the second word line and the third word line, and apply a third pass voltage to the fourth word line during a verify phase of the first program loop.

In some examples, the peripheral circuit is configured to: apply a fourth program voltage to the first word line while applying a fifth program voltage to the second word line during a program phase of a second program loop after the first program loop, where an absolute value of a difference between the fourth program voltage and the fifth program voltage is less than a third preset value, the first program voltage is less than the fourth program voltage, the second program voltage is less than the fifth program voltage, and a difference between the fourth program voltage and the first program voltage is equal to a difference between the fifth program voltage and the second program voltage.

In some examples, the peripheral circuit is configured to: apply an input voltage to the first word line and apply a fourth pass voltage to the second word line during an operation phase with the semiconductor device, where the input voltage corresponds to a first element in an input vector or an input matrix.

In some examples, the peripheral circuit includes: an analog-to-digital conversion circuit coupled to the memory array and configured to convert an analog signal into a digital signal; and a digital-to-analog conversion circuit coupled to the memory array and configured to convert a digital signal into an analog signal.

In some examples, each memory cell in the memory array is configured to store at least one bit of data.

The memory cell in the examples of the present disclosure may be configured to store at least one bit of data, and for example, the memory cell in the examples of the present disclosure may be an SLC configured to store one bit of data, or an MLC configured to store two bits of data, or a TLC configured to store three bits of data, or a QLC configured to store four bits of data, or may even be configured to store more bits of data.

In some examples, the semiconductor device may include a three-dimensional NAND type memory.

In some examples, the semiconductor device includes a first semiconductor structure and a second semiconductor structure, the memory array is located in the first semiconductor structure, the peripheral circuit is located in the second semiconductor structure, and the first semiconductor structure and the second semiconductor structure are stacked along a thickness direction of the semiconductor device.

In some examples, the semiconductor device includes a first semiconductor structure, a bonding layer, and a second semiconductor structure stacked along a thickness direction of the semiconductor device; the memory array is located in the first semiconductor structure, the peripheral circuit is located in the second semiconductor structure, and the peripheral circuit is coupled to the memory array through a bonding structure in the bonding layer.

In the examples of the present disclosure, the first semiconductor structure and the second semiconductor structure of the semiconductor device may be formed by bonding two wafers, for example, a first semiconductor structure may be formed on one wafer, a second semiconductor structure may be formed on the other wafer, and then the two wafers are bonded, and the first semiconductor structure and the second semiconductor structure are stacked along a thickness direction of the semiconductor device. In other examples, the first semiconductor structure and the second semiconductor structure of the semiconductor device may also be formed on the same wafer, but the first semiconductor structure and the second semiconductor structure are stacked along the thickness direction of the semiconductor device, and the architecture in which the first semiconductor structure and the second semiconductor structure stacked along the thickness direction of the semiconductor device can further save the area of the semiconductor device.

Here, the structure of the semiconductor device and other details are similar to those in the method of operating the semiconductor device, and will not be repeated here for brevity.

Based on the above semiconductor device, an example of the present disclosure further provides a system, including: at least one semiconductor device according to any one of the above examples and a controller coupled to the semiconductor device.

In some examples, the controller is configured to send an input vector or an input matrix to the semiconductor device and receive an operation result of the semiconductor device.

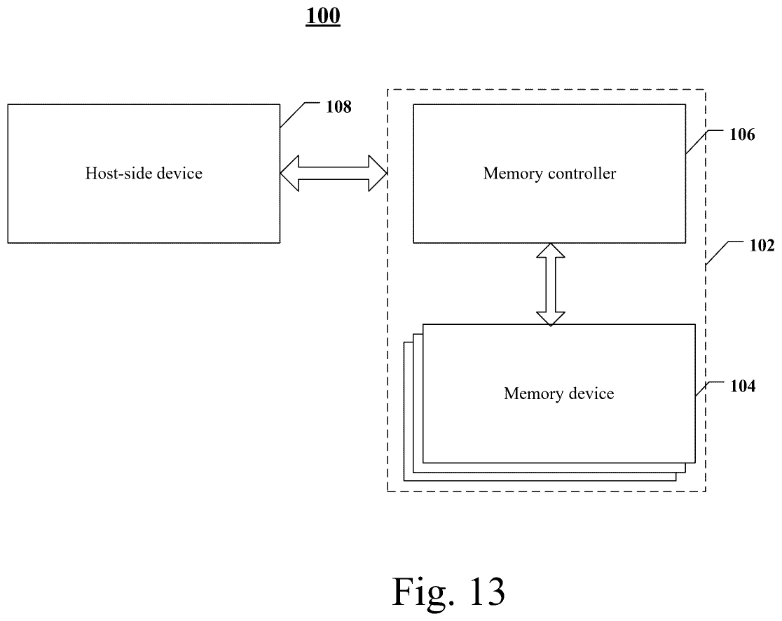

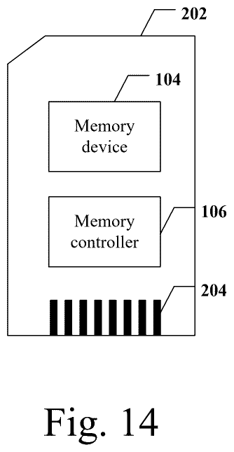

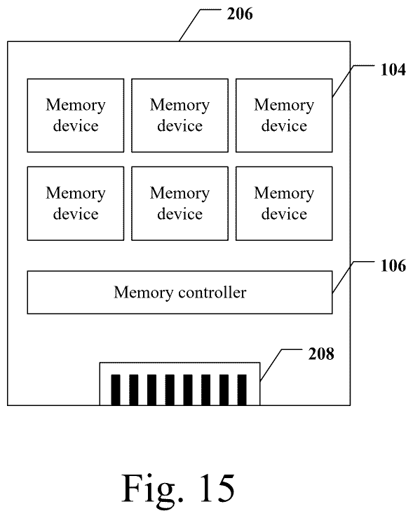

In some examples, the system in the above examples may be the memory system 102 shown in FIG. 13, the memory system 102 includes a memory controller 106 and a memory device 104 coupled to the memory controller 106, and the controller in the above examples may be the memory controller 106 shown in FIG. 13, FIG. 14, and FIG. 15.

In some other examples, the system in the above examples may be the system 100 shown in FIG. 13, the system 100 includes a host-side device 108 and a memory system 102 coupled to the host-side device 108, and the controller in the above examples may be a control part independent of the memory controller 106, for example, may be a CPU in the host-side device. The input data herein includes an input vector or an input matrix.

According to some examples, as shown in FIG. 13, the memory controller 106 is coupled to the memory device 104 and the host-side device 108 and is configured to control operations of the memory device 104, such as read, erase, program, compute operations. The memory controller 106 may manage data stored in the memory device 104 and communicate with the host-side device 108. In some examples, the memory controller 106 is designed to operate in a low duty cycle environment, such as a secure digital card, compact flash memory card, universal serial bus flash drive, or other medium for use in electronic devices such as personal computers, digital cameras, mobile phones, and the like. In some implementations, the memory controller 106 is designed to operate in a high duty cycle environment SSD or embedded multimedia card that serves as a data storage for mobile devices such as smartphones, tablet computers, laptop computers, and the like, as well as enterprise memory arrays.

The memory controller 106 and the one or more memory devices 104 may be integrated into various types of storage devices, for example, included in the same package (e.g., a Universal Flash Storage (UFS) package or an embedded multimedia card package). That is, the memory system 102 may be implemented and packaged into different types of terminal electronics. In one example as shown in FIG. 14, the memory controller 106 and the single memory device 104 may be integrated into the memory card 202. The memory card 202 may include compact flash memory cards, smart media cards, memory sticks, multimedia cards, secure digital cards, UFS, and the like. The memory card 202 may also include a memory card connector 204 that couples the memory card 202 with a host-side device (e.g., the host-side device 108 in FIG. 13). In another example as shown in FIG. 15, the memory controller 106 and the plurality of memory devices 104 may be integrated into SSD206. SSD206 may also include an SSD connector 208 that couples SSD206 with a host-side device (e.g., the host-side device 108 in FIG. 13). In some implementations, the storage capacity and/or operating speed of SSD206 is greater than the storage capacity and/or operating speed of memory card 202.

It should be understood that “one example” or “an example” mentioned throughout the specification means that specific features, structures, or characteristics related to the examples are included in at least one example of the present disclosure. Thus, “in one example” or “in an example” appearing throughout the specification need not necessarily refer to the same example. Further, these particular features, structures, or characteristics may be combined in one or more examples in any suitable manner. It should be understood that, in various examples of the present disclosure, the sequence numbers of the foregoing processes do not mean the order of execution, and the execution sequence of each process should be determined by using its function and internal logic, and should not constitute any limitation on the implementation process of the examples of the present disclosure. The foregoing sequence numbers of the examples of the present disclosure are merely for description, and do not represent the advantages and disadvantages of the examples.

The methods disclosed in the several method examples according to the present disclosure may be arbitrarily combined without conflict, to obtain a new method example.

The above descriptions are only specific implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a memory array; and
a peripheral circuit coupled to the memory array and configured to:
during a program phase of a first program loop, apply a first program voltage to a first word line and apply a second program voltage to a second word line adjacent to the first word line, wherein an absolute value of a difference between the first program voltage and the second program voltage is less than a first preset value; and
during the program phase of the first program loop, apply a first pass voltage to a third word line, wherein the first pass voltage is less than the first program voltage, and the first pass voltage is less than the second program voltage.

2. The semiconductor device of claim 1, wherein the peripheral circuit is configured to:
apply a verify voltage to the first word line and apply a second pass voltage to the second word line and the third word line during a verify phase of the first program loop.

3. The semiconductor device of claim 1, wherein the first preset value ranges from 5V to 7V.

4. The semiconductor device of claim 1, wherein the first program voltage is equal to the second program voltage.

5. The semiconductor device of claim 1, wherein:
the first word line is coupled to a plurality of first memory cells, and the second word line is coupled to a plurality of second memory cells; and
for each first memory cell of a plurality of first memory cells in a same memory slice, a threshold voltage of the first memory cell is greater than a threshold voltage of a second memory cell belonging to a same memory string as the first memory cell, or a threshold voltage of the first memory cell is less than a threshold voltage of a second memory cell belonging to a same memory string as the first memory cell, or a threshold voltage of the first memory cell is equal to a threshold voltage of a second memory cell belonging to a same memory string as the first memory cell.

6. The semiconductor device of claim 1, wherein the peripheral circuit is configured to:
apply a third program voltage to a fourth word line adjacent to the first word line while applying the first program voltage to the first word line during the program phase of the first program loop, wherein the first word line is located between the second word line and the fourth word line, and an absolute value of a difference between the first program voltage and the third program voltage is less than a second preset value.

7. The semiconductor device of claim 6, wherein the second preset value ranges from 5V to 7V.

8. The semiconductor device of claim 6, wherein the third program voltage is equal to the first program voltage, and the second program voltage is equal to the first program voltage.

9. The semiconductor device of claim 6, wherein:
the first word line is coupled to a plurality of first memory cells, and the fourth word line is coupled to a plurality of third memory cells; and
for each first memory cell of a plurality of first memory cells in a same memory slice, a threshold voltage of the first memory cell is greater than a threshold voltage of a third memory cell belonging to a same memory string as the first memory cell, or a threshold voltage of the first memory cell is less than a threshold voltage of a third memory cell belonging to a same memory string as the first memory cell, or a threshold voltage of the first memory cell is equal to a threshold voltage of a third memory cell belonging to a same memory string as the first memory cell.

10. The semiconductor device of claim 6, wherein the peripheral circuit is configured to:
apply a verify voltage to the first word line;
apply a second pass voltage to the second word line and the third word line; and
apply a third pass voltage to the fourth word line during a verify phase of the first program loop.

11. The semiconductor device of claim 1, wherein the peripheral circuit is configured to:
apply a fourth program voltage to the first word line while applying a fifth program voltage to the second word line during a program phase of a second program loop after the first program loop, wherein an absolute value of a difference between the fourth program voltage and the fifth program voltage is less than a third preset value, the first program voltage is less than the fourth program voltage, the second program voltage is less than the fifth program voltage, and a difference between the fourth program voltage and the first program voltage is equal to a difference between the fifth program voltage and the second program voltage.

12. The semiconductor device of claim 1, wherein the peripheral circuit is configured to:
apply an input voltage to the first word line and apply a fourth pass voltage to the second word line during an operation phase with the semiconductor device, wherein the input voltage corresponds to a first element in an input vector or an input matrix.

13. The semiconductor device of claim 1, wherein the peripheral circuit comprises:
an analog-to-digital conversion circuit coupled to the memory array and configured to convert an analog signal into a digital signal; and
a digital-to-analog conversion circuit coupled to the memory array and configured to convert a digital signal into an analog signal.

14. The semiconductor device of claim 1, wherein each memory cell in the memory array is configured to store at least one bit of data.

15. The semiconductor device of claim 1, wherein the semiconductor device comprises a three-dimensional NAND type memory.

16. The semiconductor device of claim 1, wherein the semiconductor device includes a first semiconductor structure, a bonding layer, and a second semiconductor structure stacked along a thickness direction of the semiconductor device, the memory array is located in the first semiconductor structure, the peripheral circuit is located in the second semiconductor structure, and the peripheral circuit is coupled to the memory array through a bonding structure in the bonding layer.

17. A system, comprising:
at least one semiconductor device, comprising:
a memory array; and
a peripheral circuit coupled to the memory array and configured to:
during a program phase of a first program loop, apply a first program voltage to a first word line and apply a second program voltage to a second word line adjacent to the first word line, wherein an absolute value of a difference between the first program voltage and the second program voltage is less than a first preset value; and
during the program phase of the first program loop, apply a first pass voltage to a third word line, wherein the first pass voltage is less than the first program voltage, and the first pass voltage is less than the second program voltage; and
a controller coupled to the semiconductor device.

18. The system of claim 17, wherein the controller is configured to send an input vector or an input matrix to the semiconductor device and receive an operation result of the semiconductor device.

19. A method of operating a semiconductor device, comprising:
during a program phase of a first program loop, applying a first program voltage to a first word line and applying a second program voltage to a second word line adjacent to the first word line, wherein an absolute value of a difference between the first program voltage and the second program voltage is less than a first preset value; and
during the program phase of the first program loop, applying a first pass voltage to a third word line, wherein the first pass voltage is less than the first program voltage, and the first pass voltage is less than the second program voltage.

20. The method of claim 19, further comprising:
applying a verify voltage to the first word line; and
applying a second pass voltage to the second word line and the third word line during a verify phase of the first program loop.
